(19) United States
(12) Patent Application Publication
(10) Pub. No.: US 2012/0042249 A1
(43) Pub. Date: Feb. 16, 2012

(54) AUDIO SIGNAL OUTPUT APPARATUS AND METHOD

(75) Inventor: WON SUK CHUNG, Seoul (KR)

(73) Assignee: LG INNOTEK CO., LTD., Seoul (KR)

(21) Appl. No.: 13/180,800

(22) Filed: Jul. 12, 2011

(30) Foreign Application Priority Data
Aug. 11, 2010 (KR) 10-2010-0077547

(51) Int. Cl. H03G 3/00; G06F 3/048; H04N 9/475

(52) U.S. Cl. 715/716; 381/107; 348/515

(57) ABSTRACT

An audio signal output apparatus is provided. The audio signal output apparatus includes an audio receiver, an audio processor, an audio output unit, and a controller. The audio receiver receives an audio data which is transmitted from outside and has a plurality of combined sounds. The audio processor signal-processes the audio data with the combined sounds to enable output. The audio output unit outputs the signal-processed audio data. The controller performs control to discretely set output levels of the respective sounds in the audio data and output the audio data with combined sounds by applying the discretely set output levels.

### CROSS-REFERENCE TO RELATED APPLICATION

This application claims the benefit under 35 U.S.C. §119 of Korean Patent Application No. 10-2010-0077547, filed on 11 Aug., 2010, which is hereby incorporated by reference in its entirety.

### BACKGROUND

The present disclosure relates to an audio signal output apparatus and method, and more particularly, to an audio signal output apparatus and method, which enable the discrete setting of output levels of respective sounds in an audio signal with combined sounds.

In display devices, generally, an audio signal is processed and outputted by a speaker system included in each of the display devices.

Therefore, a user can enjoy movies and music by using the speaker system included in the display device, and it is not inconvenient for user to view show programs and news.

However, demands of users listening to the audio signal are being increased.

FIG. 1 is a block diagram illustrating an audio signal output apparatus of the related art.

Referring to FIG. 1, the audio signal output apparatus includes a tuner 1, a sound processor 2, a speaker 3, a controller 4, and a key input unit 5.

The tuner 1 selects a channel, required by a user, from among a Radio Frequency (RF) broadcast signal of each channel received through an antenna, and outputs an Intermediate Frequency (IF) signal. The IF signal outputted from the tuner 1 is separated into a video signal and an audio signal by a detection unit (not shown), and the separated audio signal is inputted to the sound processor 2.

The sound processor 2 demodulates the input audio signal, and the speaker 3 outputs the demodulated audio signal.

At this point, when a user controls the volume of the output audio signal with the key input unit 5 having keys that are included in a remote controller or a display device, the controller 4 controls the sound processor 2 to control the level of the output audio signal.

That is, the sound processor 2 entirely controls the output level of the audio signal according to the volume. In other words, when the audio signal includes a plurality of sounds (for example, background sound, person sound, and animal sound), the sound processor 2 entirely controls the sounds according to the set volume.

Therefore, a user is required to listen to the audio signal according to a predetermined pattern, and cannot emphatically listen to only any one specific sound of the sounds.

Consequently, efficient audio signal output methods for satisfying the various requirements of users are being researched.

### BRIEF SUMMARY

Embodiments provide an audio signal output apparatus and method, which discretely adjust and output the output levels of respective sounds when outputting an audio signal with combined sounds.

The object of the present invention is not limited to the aforesaid, but other objects not described herein will be clearly understood by those skilled in the art from descriptions below.

In one embodiment, an audio signal output apparatus includes: an audio receiver receiving an audio data which is transmitted from outside and has a plurality of combined sounds; an audio processor signal-processing the audio data with the combined sounds to enable output; an audio output unit outputting the signal-processed audio data; and a controller performing control to discretely set output levels of the respective sounds in the audio data and output the audio data with combined sounds by applying the discretely set output levels.

The audio signal output apparatus may further include a storage storing a plurality of output level values based on kinds of sounds, wherein the controller may set an output level of each of the sounds by using the output level values stored in the storage.

The audio signal output apparatus may further include a display unit displaying a video data which is received in synchronization with the audio data.

The display unit may further display information regarding the sounds in the audio data, and the information of the sounds may include at least one of: kinds of the respective sounds; and location information in a display screen.

The display unit may further display a menu screen for discretely setting the output levels of the sounds.

The display unit may further display a menu screen for selecting sound to be blocked from among the sounds.

The audio signal output apparatus may further include an input unit for selecting an object, displayed in a specific region, from the video data displayed by the display unit, wherein the controller may perform control to selectively output only sound corresponding to the selected object.

The controller may detect sound corresponding to location information of the object, and remove sound other than the detected sound from the audio data.

The audio data with the combined sounds may be an audio data based on one of stereophonic sound and variable-oriented schemes.

The audio data with the combined sounds may be transmitted from at least one of a broadcasting station, a content provider, and an external device.

In another embodiment, an audio signal output method include: receiving an audio data with a plurality of combined sounds; discretely setting output levels of the respective sounds in the audio data; and outputting the audio data with the combined sounds by applying the discretely set output levels.

The setting of output levels may include: checking kinds of the sounds in the audio data; extracting output levels of the checked sounds from a pre-stored output level adjustment table; and setting the output levels of the sounds to the extracted output levels, respectively.

The setting of output levels may include: displaying a menu screen for setting the output levels of the sounds in the audio data; and setting the output levels of the sounds on the basis of a plurality of output levels displayed on the menu screen.

The menu screen may include one of: a first setting region for discretely setting the output levels of the respective sounds; and a second setting region for selecting sound, intended to block an output, from among the sounds.

The setting of output levels may include: displaying a video data which is received in synchronization with the audio data; selecting an object, included in a specific region, from the displayed video data; and setting an output level of sound other than sound, corresponding to the selected object, to 0.

The setting of an output level to 0 may include: detecting sound, corresponding to location information of the selected object, from the received audio data; and removing sound other than the detected sound from the audio data.

The audio signal output method may further include an operation where a volume adjustment event occurs, wherein the setting of output levels may be performed at a time when the volume adjustment event occurs.

The details of one or more embodiments are set forth in the accompanying drawings and the description below. Other features will be apparent from the description and drawings, and from the claims.

### BRIEF DESCRIPTION OF THE DRAWINGS

FIG. 1 is a block diagram illustrating a configuration of an audio signal output apparatus of the related art.

FIG. 2 is a block diagram illustrating a configuration of an audio signal output apparatus according to an embodiment.

FIGS. 3 to 8 are diagrams for describing an operation of setting an output level of an audio signal according to an embodiment.

FIGS. 9 to 12 are flowcharts illustrating respective operations of an audio signal output method according to an embodiment.

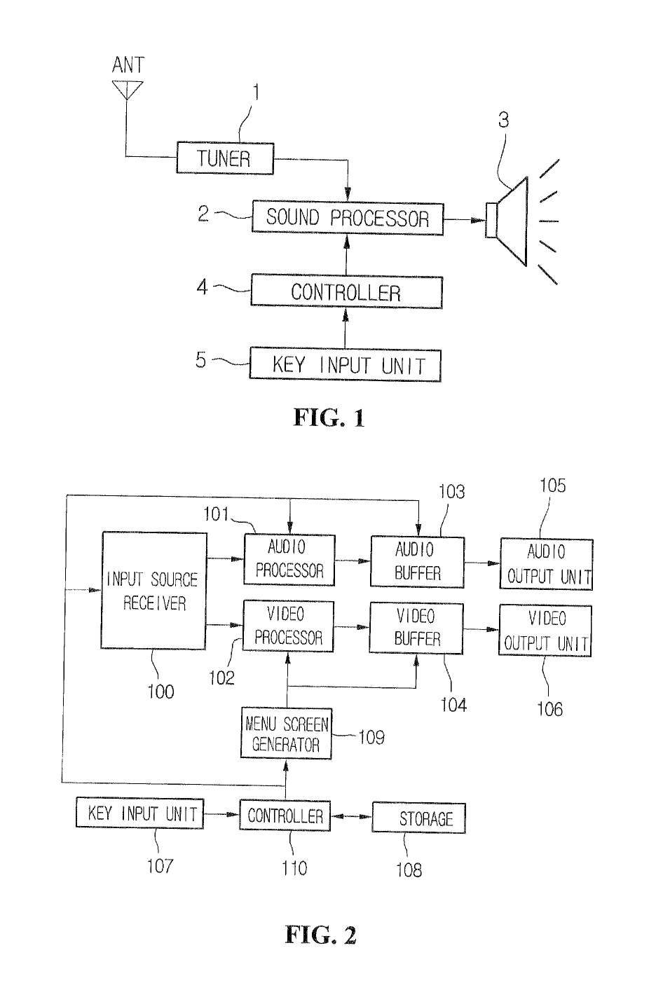

### DETAILED DESCRIPTION

The present invention may be variously modified and have several embodiments, and thus, specific embodiments are illustrated in drawings and will be described.

Thus, it is intended that the present invention covers the modifications and variations of this invention provided they come within the scope of the appended claims and their equivalents.

Terms like a first and a second may be used to describe various elements, but the elements should not be limited by the terms. The terms may be used only as object for distinguishing an element from another element. For example, without departing from the spirit and scope of the inventive concept, a first element may be referred to as a second element, and similarly, the second element may be referred to as the first element. As used herein, the term and/or includes any and all combinations of one or more of the associated listed items.

It will also be understood that when an element is referred to as being ‘on’ another element, it can be directly on the other element, or intervening elements may also be present.

Further, it will be understood that when an element is referred to as being ‘under’ another element, it can be directly under, and one or more intervening elements may also be present. In addition, it will also be understood that when an element is referred to as being ‘between’ two elements, it can be the only element between the two elements, or one or more intervening elements may also be present.

In the following description, the technical terms are used only for explain a specific exemplary embodiment while not limiting the present invention. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

Unless terms used in embodiments of the inventive concept are defined differently, the terms may be construed as meaning known to those skilled in the art. Terms such as terms that are generally used and have been in dictionaries should be construed as having meanings matched with contextual meanings in the art. In this description, unless defined clearly, terms are not ideally, excessively construed as formal meanings.

Reference will now be made in detail to the embodiments of the present disclosure, examples of which are illustrated in the accompanying drawings. To enable easy understanding in describing the present invention, like reference numerals refer to like elements throughout.

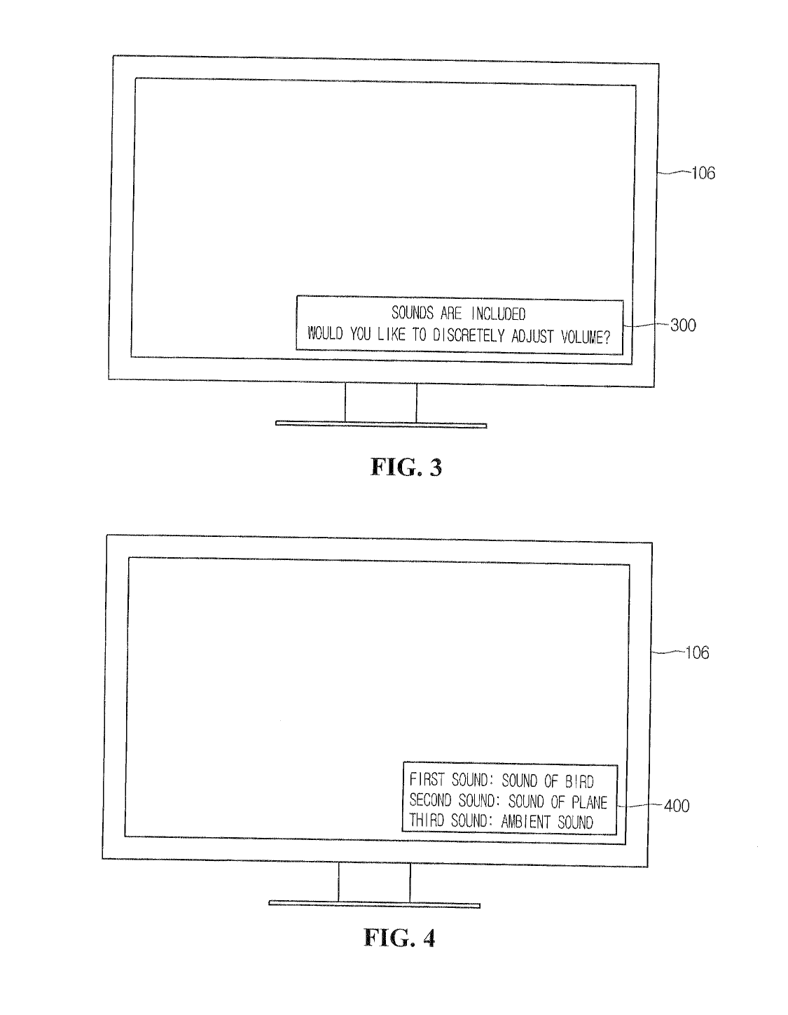

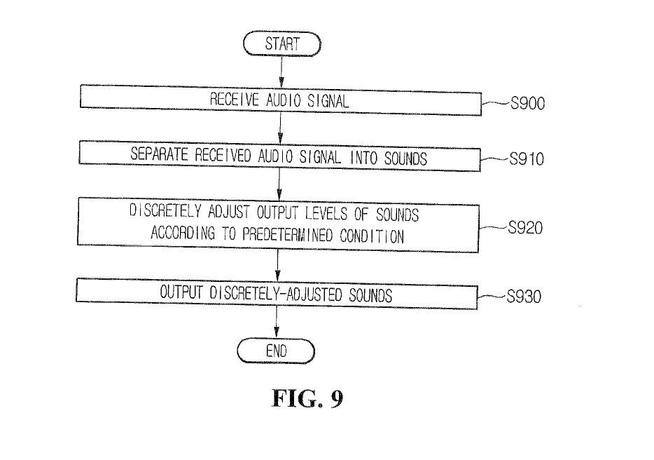

FIG. 2 is a block diagram illustrating a configuration of an audio signal output apparatus according to an embodiment. FIGS. 3 to 8 are diagrams for describing an operation of setting an output level of an audio signal according to an embodiment. FIGS. 9 to 12 are flowcharts for describing an audio signal output method by stages, according to an embodiment.

Referring to FIG. 2, the audio signal output apparatus according to an embodiment includes an input source receiver 100, an audio processor 101, a video processor 102, an audio buffer 103, a video buffer 104, an audio output unit 105, a video output unit 106, a key input unit 107, a storage 108, a menu screen generator 109, and a controller 110.

The input source receiver 100 receives an input source that is transmitted through various paths.

That is, the input source receiver 100 may be a digital tuner receiving a digital broadcast signal, an analog tuner receiving an analog broadcast signal, a digital external signal input terminal connected to an external device, an analog external signal input terminal connected to an external device, a digital recorder such as a Personal Video Recorder (PVR) or a Digital Video Recorder (DVR), or a network interface that receives data, which are provided by an Internet or content provider or a network operator, over a network.

Herein, the digital external signal input terminal may be an input terminal for a digital cable broadcast signal or a terminal that may be connected to a digital external player such as a DVD. The analog external signal input terminal may be a VCR signal input terminal or an input terminal for an analog cable broadcast signal.

Moreover, the digital tuner tunes a transport stream of a specific channel that is selected by the user from among Transport Streams (TS), being digital broadcast signals, which are inputted through an antenna for digital broadcast. Moreover, the analog tuner tunes an image program of a specific channel that is selected by the user from among a plurality of image programs, being analog broadcast signals, which are inputted through an antenna for analog broadcast.

Therefore, data inputted through the input source receiver 100 may include an analog television (TV) broadcast program that is being broadcasted in real time, a digital broadcast program, a replay program inputted from an external player, a record program, and a cable broadcast program. Herein, in a case of a digital signal, the broadcast data includes a video signal, an audio signal, and an additional information signal. In a case of an analog signal, the broadcast data only includes a video signal and an audio signal.

The input source receiver 100 may receive a digital image data that is generated by compressing an image displayed by an external device such as a TV, a Personal Computer (PC), a Personal Digital Assistant (PDA), or a portable phone, and is then transmitted over Bluetooth or wireless Local Area Network (LAN). Thus, the input source receiver 100 may include a Bluetooth reception module or a wireless LAN reception module. In this embodiment, Bluetooth or wireless LAN is applied as an example of a transmission scheme, but this embodiment is not limited thereto. As another example, a transmission scheme applied to this embodiment is not specially limited in a case of a communication protocol that is wirelessly connected to a computer, a mobile terminal, or a home appliance, which is in a distance close from a display device, and enables real-time two-way communication.

Thus, the input source receiver 100 may include a Universal Serial Bus (USB) port or a memory card slot, and receive a recorded image data recorded from an image record medium such as a digital camera. Herein, the memory card may include a Compact Flash (CF) card, a Smart Media (SM) card, a memory stick, a multimedia card (MMC), a micro drive, an XD picture card, or a Secure Digital (SD) card.

An audio signal in an input source received through the input source receiver 100 is processed by the audio processor 101 and outputted by the audio output unit 105.

The audio processor 101 may be implemented with an AC-3 processor, and the audio output unit 105 may be implemented with at least one speaker.

Moreover, a video signal in the input source received through the input source receiver 100 is signal-processed by the video processor 102, and displayed by the video output unit 106. In this case, the audio signal may be an audio data that is generated by one of stereophonic sound and variable-oriented schemes.

The video processor 102 may include an MPEG-2 decoder, and a scalier that converts a video data to be suitable for a vertical frequency, resolution, and a screen size that are based on an output standard of a video output apparatus.

The video output unit 106 may be applied to various types of display modules such as Digital Light Processing (DLP), Liquid Crystal Displays (LCDs), and Plasma Display Panels (PDPs). An image displayed by the video output unit 106 may be a still image or a moving image, and be a Two-Dimensional (2D) image or a Three-Dimensional (3D) image.

The audio buffer 103 temporarily stores an audio signal processed by the audio processor 101, and the video buffer 104 temporarily stores a video signal processed by the video processor 102. The audio buffer 103 and the video buffer 104 may be referred to as a synchronizer for synchronizing the output timing of the audio signal with the output timing of the video signal, or a delayer for delaying an output time of the audio signal and an output time of the video signal for a certain time.

That is, the audio buffer 103 temporarily stores the audio signal outputted from the audio processor 101 for a time, corresponding to a predetermined audio signal output delay value, with respect to the output time of the video signal and then outputs the stored audio signal.

The video buffer 104 temporarily stores the video signal outputted from the video processor 102 for a time, corresponding to a predetermined video signal output delay value, with respect to the output time of the audio signal and then outputs the stored video signal.

The key input unit 107 is a means for receiving a requirement command from a user, and may be configured with a local key input unit that is disposed at one side of a front cover of the audio signal output apparatus, or an infrared light receiver for receiving an infrared signal transmitted from a remote controller.

For example, the key input unit 107 may a user input signal, which is inputted from a local key input unit such as a power key, a channel key, a volume key, and a setting key, to the controller 110 that will be described below.

Moreover, the key input unit 107 may transfer a user input signal, inputted from a sensing unit (not shown) for sensing a user's gesture, to the controller 110 or transmit a signal, inputted from the controller 110, to the sensing unit. Herein, the sensing unit may include a touch sensor, a sound sensor, a position sensor, and a motion sensor.

The storage 108 may include at least one storage medium of a flash memory, a hard disk, a multimedia card micro type of memory, a card type of memory (for example, an SD memory, an XD memory, or the like), a Random Access Memory (RAM), a Read-Only Memory (ROM, for example, Electrically Erasable and Programmable Read-Only Memory (EEPROM)), The audio signal output apparatus replays a file (for example, a moving image file, a still image file, a music file, a document file, or the like) stored in the storage 108 to provide the file.

The storage 108 stores information that is obtained while the audio signal output apparatus is operating, or information necessary for an operation of the audio signal output apparatus.

Particularly, the storage 108 stores an output level adjustment table including predetermined output levels by kinds of sounds.

That is, the sounds may include may include at least one of person sound, thing sound, animal sound, and background sound.

FIG. 2 illustrates an embodiment that separately includes the storage 108 and the controller 110, but the scope and spirit of this embodiment are not limited thereto. As another example, the storage 108 may be included in the controller 110.

The menu screen generator 109 generates an On Screen Display (OSD) signal according to a user input or autonomously. For example, the menu screen generator 109 may generate a signal for displaying various information as graphics or texts on a screen of the video output unit 106, on the basis of a user input signal. The generated signal may include various data such as a user interface screen, various menu screens, Widget, and an icon. Also, the generated signal may include a 2D object or a 3D object.

The controller 110 controls an overall operation of the audio signal output apparatus. For example, the controller 110 may control the input source receiver 100 such that specific data selected by a user is received and outputted.

In particular, the controller 110 checks a plurality of sounds in an audio signal received through the input source receiver 100, and allows the output levels of the checked sounds to discretely be adjusted and outputted.

For example, the audio signal may include a plurality of combined sounds corresponding to person sound, animal sound, and ambient background sound.

Therefore, the controller 110 performs control such that the output levels of the respective sounds are discretely set, the discretely-set output levels are applied, and the audio signal including the sounds is outputted.

For example, the controller 110 may set an output level of person sound, included in the audio signal, to a first level. The controller 110 may set an output level of ambient sound, included in the audio signal, to a second level. Herein, the first and second levels may be the same or differ.

Thus, the audio processor 101 separates the received audio signal into a plurality of sounds, and signal-processes the separated sounds by applying the output levels that have been set by the controller 110.

In this case, the output levels of the respective sounds may be set by various schemes.

For example, the output levels may be preset by a user by kinds of sounds.

That is, the user may set an output level corresponding to each sound, based on the kinds of sounds. The output level set by the user may be stored in the storage 108.

When the audio signal is received, the controller 110 checks the kind of each sound in the received audio signal. Subsequently, the controller 110 extracts an output level, corresponding to the kind of each sound, from the output adjustment table stored in the storage 108. Furthermore, the controller 110 outputs a control signal such that the extracted output level is applied and the each sound is signal-processed. The audio processor 101 performs the signal processing of the each sound according to the control signal of the controller 110.

Moreover, the output level may be set by a user at a time when the audio signal is outputted.

For this, when the audio signal is received, the controller 110 performs control in order to display a menu screen for setting the output levels of sounds in the discretely received audio signal.

The menu screen generator 109 generates a menu screen for setting the output levels of the sounds according to the control signal of the controller 110, and the generated menu screen is displayed by the video output unit 106. Herein, the menu screen may be displayed in combination with the video signal that has been received together with the audio signal.

When a predetermined event occurs, the controller 110 may allow the menu screen to be displayed. The event may include a case where a volume adjustment event occurs by a user.

That is, when a volume adjustment signal of an audio signal is inputted through the key input unit 107, the controller 110 performs control in order to display a menu screen for setting the output levels of respective sounds in the audio signal.

Referring to FIG. 3, when the volume adjustment event occurs, the controller 110 may perform control so as to display a menu screen 300 that inquires for whether to discretely adjust the output levels of sounds. The audio signal includes a plurality of sounds, and thus the menu screen 300 may include a guidance phrase that inquires for whether to discretely adjust the output levels of sounds.

The menu screen 300 including the guidance phrase is generated by the menu screen generator 109 and displayed by the video output unit 106.

Referring to FIG. 4, when the user inputs a discrete output level setting command while the menu screen 300 is being displayed, the controller 110 allows information of the sounds in the audio signal to be displayed. That is, the controller 110 performs control in order to display information 400 that enables to check what sounds are included in a currently received audio signal.

The information 400 may include sounds included in the audio signal, and the kinds of sounds (for example, bird sound, plane sound, and ambient sound).

Subsequently, the controller 110 performs control such that a menu screen for setting the output levels of respective sounds in the audio signal is displayed.

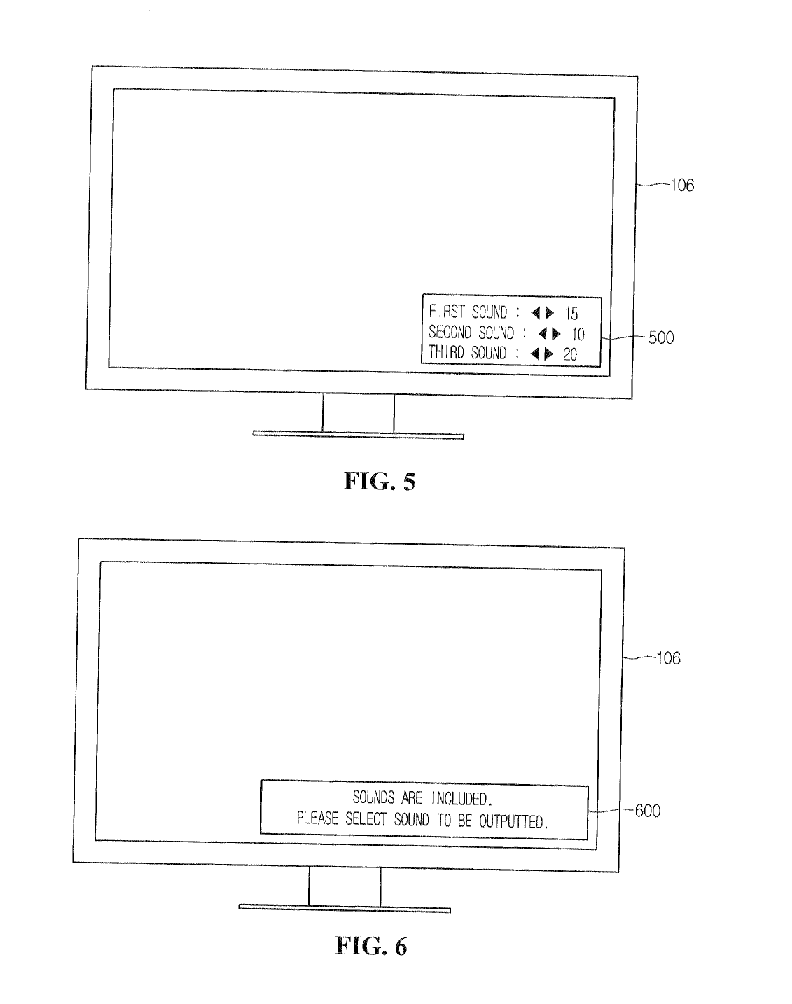

Referring to FIG. 5, the controller 110 performs control so as to display a menu screen 500 for setting the output levels of respective sounds in the audio signal. The menu screen 500 may include an output level setting window enabling the setting of the output levels of respective sounds. For example, when the respective sounds in the audios signal are first to third sounds, the menu screen 500 may include a first output level setting window for setting an output level of the first sound, a second output level setting window for setting an output level of the second sound, and a third output level setting window for setting an output level of the third sound.

When the output levels of respective sounds are set with the menu screen 500 of FIG. 5, the controller 110 performs control such that the set output levels are applied and the sounds in the audio signal are signal-processed.

In another embodiment, a user may select specific sound, intended to output or block, from among a plurality of sounds.

For this, as illustrated in FIG. 6, the controller 110 allows a menu screen 600 including a guidance phrase to be displayed such that the user selects specific sound, intended to output or block, from among the sounds.

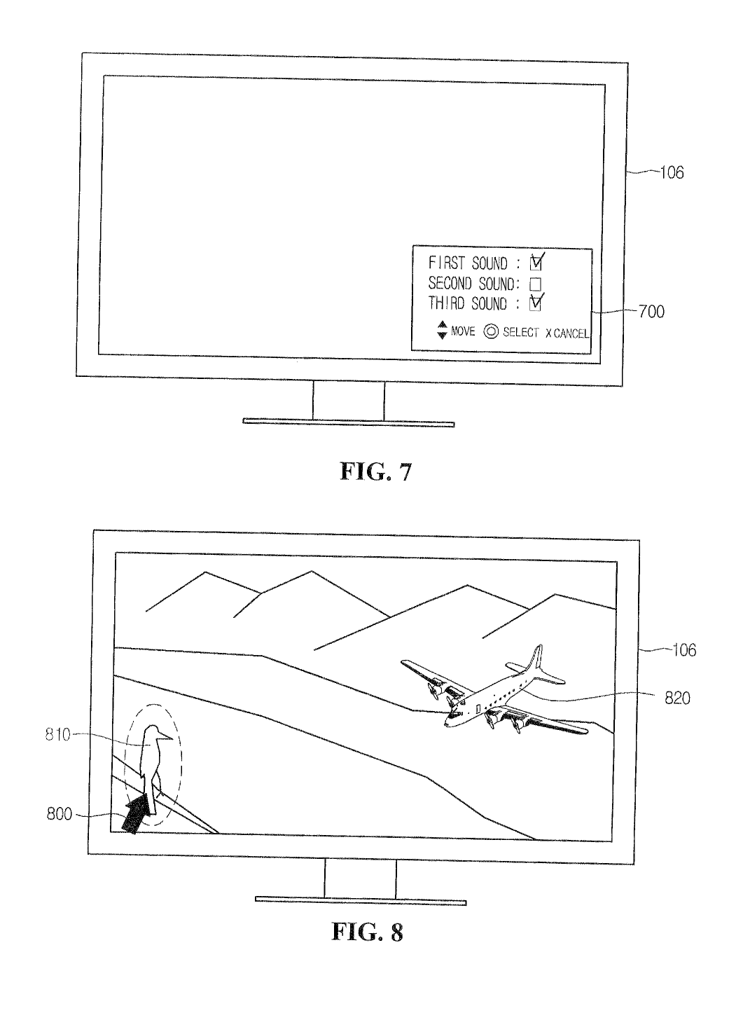

Subsequently, as illustrated in FIG. 7, the controller 110 performs control in order to display a menu screen 700 including a selection window that enables to select sound, intended to output or block, from among the sounds in the audio signal. For example, when the audio signal includes first to third sounds, the menu screen 700 includes a first selection window enabling to set whether to output or block the first sound, a second selection window enabling to set whether to output or block the second sound, and a third selection window enabling to set whether to output or block the third sound.

When sound to be outputted or blocked is selected with the displayed selection window of the menu screen 700, the controller 110 performs control so as to output only the sound that has been selected through output.

That is, the controller 110 performs control such that the output level of the sound that has been selected through output is set to a specific value (for example, a level of 10) instead of 0, the output level of the sound that has been selected through blocking is set to 0, and the sounds in the audio signal are signal-processed according to the set output levels.

In another embodiment, the controller 110 extracts the sound, which has been selected through output, from the audio signal, and thus removes sound other than the extracted sound from the audio signal. Therefore, the audio signal includes only the sound that has been selected by a user through output.

Moreover, the user may select sound, intended to output or block, from among the sounds while viewing a display screen.

That is, as illustrated in FIG. 8, a video signal that is received in synchronization with the audio signal is displayed by the video output unit 106. Herein, an image outputted by the video output unit 106 may include a plurality of objects. The objects may correspond to the sounds in the audio signal, respectively. For example, when the image includes a bird 810, the audio signal may include sound corresponding to sound of the bird 810, or when the image includes a plane 820, the audio signal may include sound corresponding to sound of the plane 820.

Therefore, the user may select a specific object of the objects included in the displayed image, by using a pointer 800 displayed by a space recognition remote controller.

When a specific object is selected with the pointer 800, the controller 110 checks information of location at which the selected object is located. The location information may be information of a coordinate at which the object is displayed on a display screen.

When the location information of the selected object is checked, the controller 110 checks a sound signal corresponding to the location information. That is, additional information received together with the audio signal may include location information of each sound in the audio signal, and the controller 110 checks sound corresponding to the object selected by the user, on the basis of the location information included in the additional information.

Subsequently, as described above, the controller 110 allows only sound corresponding to the selected object to be outputted, and the output of other sounds is blocked.

Hereinafter, an audio signal output method according to an embodiment will be described with reference to the accompanying drawings.

FIGS. 9 to 12 are flowcharts illustrating respective operations of an audio signal output method according to an embodiment.

Referring to FIG. 9, first, the audio signal output apparatus receives an audio signal transmitted from the outside in operation S900. The audio signal may be an audio data that has been generated by one of stereophonic sound and variable-oriented schemes.

Subsequently, the audio signal output apparatus separates the received audio signal into a plurality of sounds in operation S910. That is, the audio signal may include a plurality of sounds. When the audio signal includes the sounds, the audio signal output apparatus separates the audio signal into the sounds.

Subsequently, the audio signal output apparatus discretely adjusts the output levels of the respective separated sounds according to a predetermined condition in operation S920.

That is, the audio signal output apparatus first checks the kinds of separated sounds, and determines an output level corresponding to the checked kind with a predetermined output level adjustment table. Furthermore, the audio signal output apparatus signal-processes the sounds in the audio signal by applying the checked output level.

Subsequently, the audio signal that has been signal-processed by discretely applying the output levels according to the sound is outputted in operation S930.

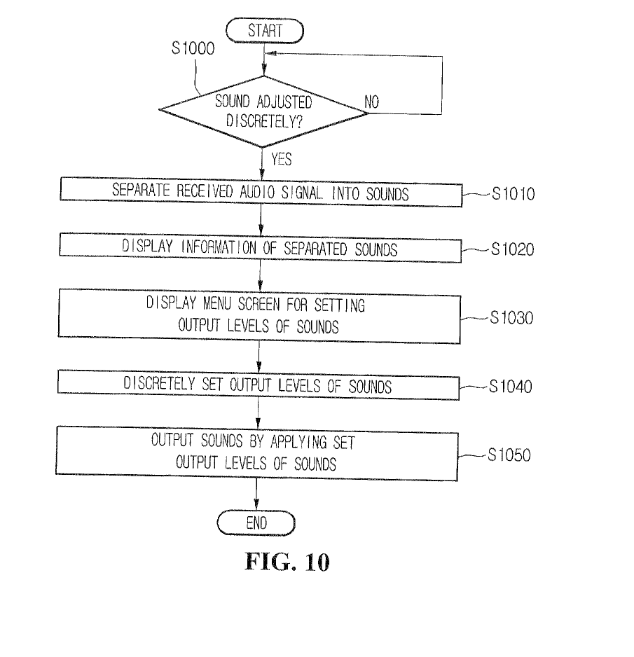

Referring to FIG. 10, the audio signal output apparatus determines whether a discrete sound adjustment command is inputted in operation S1000. The discrete sound adjustment command may be inputted in response to a case where a volume adjustment event occurs.

When the discrete sound adjustment command is inputted, the audio signal output apparatus separates the received audio signal into a plurality of sounds in operation S1010.

When the audio signal is separated into the sounds, the audio signal output apparatus checks information regarding the separated sounds, and displays the information of the sounds in operation S1020. That is, the audio signal output apparatus displays information indicating what sound is included in the received audio signal.

Subsequently, the audio signal output apparatus displays a menu screen enabling to set the output levels of the respective sounds in operation S1030. The displayed menu screen includes an output level setting window that enables the setting of an output level to be applied to each of the sounds in the audio signal.

Subsequently, a user sets the output level to be applied to each of the sounds by using the displayed menu screen in operation S1040.

Subsequently, when the output level is set, the audio signal output apparatus signal-processes the sounds by applying the set output levels of the respective sounds, and outputs an audio signal including the signal-processed sounds in operation S1050.

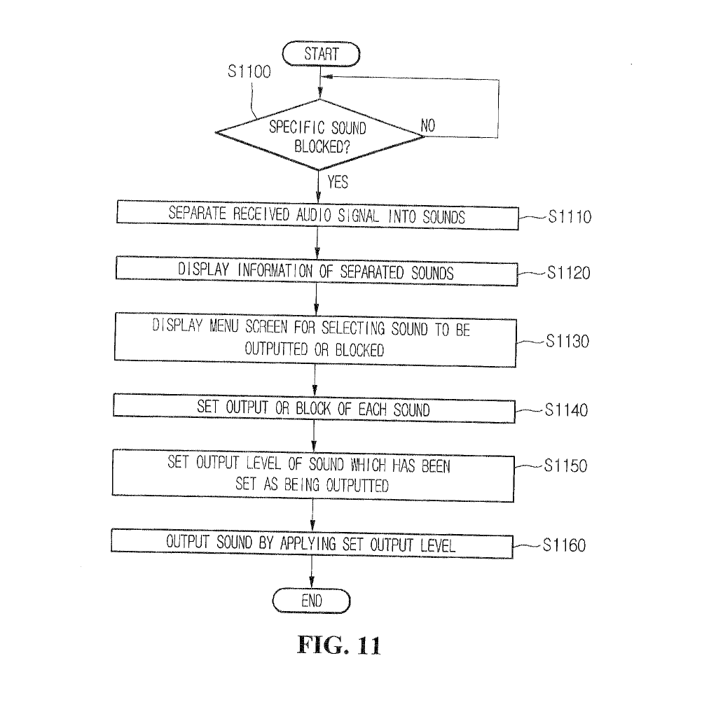

Referring to FIG. 11, the audio signal output apparatus determines whether a specific sound blocking command for outputting only specific sound of the sounds is inputted in operation S1100. The specific sound blocking command may be inputted in response to a case where a volume adjustment event occurs.

When the specific sound blocking command is inputted, the audio signal output apparatus separates the received audio signal into a plurality of sounds in operation S1110.

When the audio signal is separated into the sounds, the audio signal output apparatus checks information regarding the separated sounds, and displays the information of the sounds in operation S1120. That is, the audio signal output apparatus displays information indicating what sound is included in the received audio signal.

Subsequently, the audio signal output apparatus displays a menu screen that enables to select sound, intended to output or block, from among the sounds in operation S1130.

Subsequently, a user selects sound to be outputted from among the sounds in the audio signal, by using the displayed menu screen in operation S1140.

Subsequently, when the sound to be outputted is selected, the audio signal output apparatus removes sound other than the selected sound from the sounds in the audio signal, and signal-processes and outputs only the selected sound in operations S1150 and S1160. Herein, the audio signal output apparatus sets an output level of the selected sound to a specific level instead of 0, and sets an output level of the sound, which has been selected through blocking, to 0, thereby allowing only the selected specific sound to be outputted.

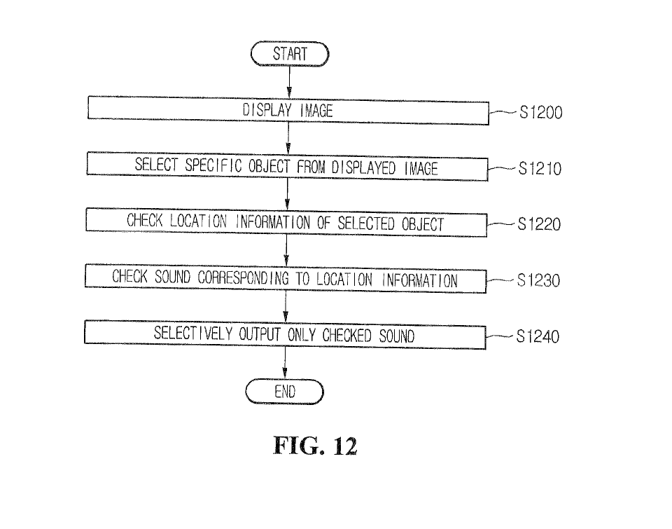

Referring to FIG. 12, the audio signal output apparatus displays a video signal (i.e., an image) that is received in synchronization with the audio signal in operation S1200. Herein, the image may include a plurality of objects.

In operation S1210, the user selects any one specific object from among the objects in the image. The selected object may be an object corresponding to sound intended to output.

When the object is selected, the audio signal output apparatus checks a location of the selected object in operation S1220, and checks sound corresponding to checked location in operation S1230. That is, the audio signal output apparatus checks sound that is emitted from the selected object.

When the sound is checked, the audio signal output apparatus removes sound other than the checked sound from the sounds in the received audio signal, and outputs an audio signal not having the removed sound in operation S1240.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An audio signal output apparatus comprising:
an audio receiver receiving an audio data which is transmitted from outside and has a plurality of combined sounds;
an audio processor signal-processing the audio data with the combined sounds to enable output;
an audio output unit outputting the signal-processed audio data; and
a controller performing control to discretely set output levels of the respective sounds in the audio data, and output the audio data with combined sounds by applying the discretely set output levels.

2. The audio signal output apparatus according to claim 1, further comprising a storage storing a plurality of output level values based on kinds of sounds,
wherein the controller sets an output level of each of the sounds by using the output level values stored in the storage.

3. The audio signal output apparatus according to claim 1, further comprising a display unit displaying a video data which is received in synchronization with the audio data.

4. The audio signal output apparatus according to claim 3, wherein,
the display unit further displays information regarding the sounds in the audio data, and
the information of the sounds comprises at least one of: kinds of the respective sounds; and location information in a display screen.

5. The audio signal output apparatus according to claim 3, wherein the display unit further displays a menu screen for discretely setting the output levels of the sounds.

6. The audio signal output apparatus according to claim 3, wherein the display unit further displays a menu screen for selecting sound to be blocked from among the sounds.

7. The audio signal output apparatus according to claim 3, further comprising an input unit for selecting an object, displayed in a specific region, from the video data displayed by the display unit,
wherein the controller performs control to selectively output only sound corresponding to the selected object.

8. The audio signal output apparatus according to claim 7, wherein the controller detects sound corresponding to location information of the object, and removes sound other than the detected sound from the audio data.

9. The audio signal output apparatus according to claim 1, wherein the audio data with the combined sounds is an audio data based on one of stereophonic sound and variable-oriented schemes.

10. The audio signal output apparatus according to claim 1, wherein the audio data with the combined sounds is transmitted from at least one of a broadcasting station, a content provider, and an external device.

11. An audio signal output method comprising:
receiving an audio data with a plurality of combined sounds;
discretely setting output levels of the respective sounds in the audio data; and
outputting the audio data with the combined sounds by applying the discretely set output levels.

12. The audio signal output method according to claim 11, wherein the setting of output levels comprises:
checking kinds of the sounds in the audio data;
extracting output levels of the checked sounds from a pre-stored output level adjustment table; and
setting the output levels of the sounds to the extracted output levels, respectively.

13. The audio signal output method according to claim 11, wherein the setting of output levels comprises:
displaying a menu screen for setting the output levels of the sounds in the audio data; and
setting the output levels of the sounds on the basis of a plurality of output levels displayed on the menu screen.

14. The audio signal output method according to claim 13, wherein the menu screen comprises one of: a first setting region for discretely setting the output levels of the respective sounds; and a second setting region for selecting sound, intended to block an output, from among the sounds.

15. The audio signal output method according to claim 11, wherein the setting of output levels comprises:
displaying a video data which is received in synchronization with the audio data;
selecting an object, comprised in a specific region, from the displayed video data; and
setting an output level of sound other than sound, corresponding to the selected object, to 0.

16. The audio signal output method according to claim 15, wherein the setting of an output level to 0 comprises:
detecting sound, corresponding to location information of the selected object, from the received audio data; and
removing sound other than the detected sound from the audio data.

17. The audio signal output method according to claim 11, further comprising an operation where a volume adjustment event occurs,
wherein the setting of output levels is performed at a time when the volume adjustment event occurs.
